(19) United States
(12) Patent Application Publication
(10) Pub. No.: US 2021/0125842 A1
(43) Pub. Date: Apr. 29, 2021

(54) Conversion Joint, Integrated Fluid Supply Device Having Said Conversion Joint, and Method for Mounting a Fluid Part

(71) Applicant: Fujikin Incorporated, Osaka-shi (JP)

(72) Inventors: Ryosuke Iwasawa, Osaka-shi (JP); Hidehiro Doya, Osaka-shi (JP)

(21) Appl. No.: 16/497,142

(22) PCT Filed: Mar. 9, 2018
(86) PCT No.: PCT/JP2018/009248

§ 371 Date: Sep. 24, 2019

(30) Foreign Application Priority Data
Mar. 29, 2017 (JP) 2017-064919

(51) Int. Cl. H01L 21/67; F16L 41/02

(52) U.S. Cl. CPC H01L 21/67017; F16L 41/02

(57) ABSTRACT

A conversion joint making possible the use a fluid part having a different size from another fluid part, the conversion joint includes a first base portion a second base portion separated from the first base portion, an intermediate portion connecting the first base portion and the second base portion, a one end side flow path and connected to one end of a first flow path of the base block, and an other end side flow path connected to the other end of a second flow path of the base block, wherein the first opening of second base portion of the one end flow path and the second opening of the other end flow path on the second base side can connect the fluid inlet of the first fluid part and the fluid outlet of the first fluid part.

### TECHNICAL FIELD

The present invention relates to a conversion joint, an integrated fluid supply device having the conversion joint, and a method of mounting a fluid part.

### BACKGROUND ART

Conventionally, in a semiconductor manufacturing apparatus, an integrated fluid supply device (hereinafter also referred to as an integrated fluid supply device) is used in a supply line for supplying various gases (see Patent Document 1).

Specifically, fluid parts such as a manual valve, a pressure transducer, a regulator, a filter, a mass flow controller, and an air operation valve are used for one gas supply line, and the width of the fluid parts in the alignment direction is compactly integrated by forming the fluid inlet and the fluid outlet of the fluid parts at the lower side and disposing a base block forming a flow path connecting the fluid parts at the lower side of the fluid parts.

### PRIOR ART DOCUMENT

### Patent Document

[Patent Document 1] Japanese Patent Application Laid-open Publication No. 2002-130479

### DISCLOSURE OF INVENTION

### Problem to be Solved by the Invention

Then, for integrated fluid supply devices, there was a time when a base block having an outer size of approximately 1.5 inches and fluid parts corresponding to the base block were used, but due to further integration requirements, currently a base block having an outer size of approximately 1.125 inches is used mainly, and each fluid part also corresponds to a base block having an outer size of 1.125 inches.

However, recently, the integrated fluid supply device of the 1.5-inch base block used in the past has been revived, and users who produce small scale semiconductor wafers and/or users who produce semiconductor wafers by purchasing a 1.5-inch base block integrated fluid supply device in the second-hand market, etc. have appeared.

Then, as these users replace the fluid parts, there is an inquiry for the fluid parts corresponding to the 1.5-inch base block, but at present, because fluid parts compatible with a 1.5-inch base block are produced upon receipt of order, there is a problem that they are expensive and have a long delivery time. In some cases, the 1.5 inch fluid parts have even been discontinued from production, and often only the 1.125 inch fluid parts are produced.

The present invention has been made in view of the above circumstances, and an object of the present invention is to provide an integrated type fluid supply device having a conversion joint and a conversion joint that enables use of a fluid part having a different size from that of a fluid part corresponding to a base block.

### Means for Solving the Problem

The present invention is grasped by the following composition in order to achieve the above-mentioned object.

(1) A conversion joint having flow paths connecting a first flow path in a base block and a second flow path in a base block, the conversion joint comprising a first base portion disposed on the base blocks, a second base portion which is separated from the first base portion in a first direction away from the base blocks and on which a first fluid part is mounted having a size different from other fluid parts to be mounted on the base blocks in the places where the conversion joint is mounted, an intermediate portion located between the first base portion and the second base portion which connects the first base portion and the second base portion, a one end side flow path penetrating the second base portion, the intermediate portion, and the first base portion and connected to one end of the first flow path of the base block, and

an other end side flow path penetrating the second base portion, the intermediate portion, and the first base portion and connected to the other end of the second flow path of the base block, wherein a first opening of second base portion of the one end flow path and a second opening of the other end flow path on the second base side are set to be connectable to the fluid inlet of the first fluid part and the fluid outlet of the first fluid part.

(2) In the configuration of the above (1), wherein the first base portion is formed to have a first outer shape having a substantially rectangular shape in which one of two sets of opposite side surfaces is disposed along a second direction with respect to the direction from the fluid inlet to the fluid outlet of the first fluid part, wherein the second base portion is formed in a substantially rectangular shape having a second outer shape different from the first outer shape, and wherein the intermediate portion has a first width in a third direction orthogonal to the first direction and the second direction which is larger than a first inner diameter of the one end side flow path and a second inner diameter of the other end side flow path, and the first width is smaller than either of the distances between opposite sides of the two first outer shapes.
(3) In the configuration of the above (2), wherein the intermediate portion has a first width that is less than either of the distances between the opposite side surfaces of the second outer shape having two sets.
(4) In the configurations of the above (2) or (3), wherein in the first base part, four screw penetration portions are provided at positions forming a rectangular shape, wherein in the second base part, four screw engagement portions are provided at positions forming a rectangular shape, and wherein the intermediate portion has a first width less than any distance between the four adjacent screw penetration portions and less than any distance between the four adjacent screw engagement portions.
(5) In the configuration of the above (4), wherein when viewed in a direction in which the first base portion and the second base portion overlap with each other with the second base portion facing the front, the second base portion overlaps at least part of a portion where a screw of the screw penetration portions is positioned, and wherein the screw penetration portions are formed in the first base portion as notches opened to the side surface of the first base portion.
(6) In the configuration of any of the above (1)-(5), wherein the first inner diameter of the one end side flow path between the first opening and a third opening on the first base portion side of the one end side flow path is a substantially uniform inner diameter, wherein the third opening has a diameter larger than the first inner diameter of the one end side flow path, wherein the second inner diameter of the other end side flow path between the second opening and a fourth opening on the first base portion side of the other end side flow path is a substantially uniform inner diameter, and wherein the fourth opening is larger in diameter than the second inner diameter of the other end side flow path.
(7) An integrated fluid supply device comprising at least a conversion joint according to any one of the above configurations (1)-(6), base blocks, and a first fluid part.
(8) A method for attaching a fluid part using a conversion joint having a first flow path formed in a base block and a flow path connected to a second flow path, the conversion joint comprising a first base portion disposed on the base block, a second base portion separated from the first base portion in a first direction away from the base block and mounted with a first fluid part of a size different from the fluid part mounted where the conversion joint of the base block is provided, an intermediate portion located between the first base portion and the second base portion which connects the first base portion and the second base portion, a one end side flow path penetrating the second base portion, the intermediate portion, and the first base portion and connected to one end of the first flow path of the base block, and an other end side flow path penetrating the second base portion, the intermediate portion, and the first base portion and connected to the other end of the second flow path of the base block, wherein a first opening of second base portion of the one end flow path and a second opening of the other end flow path on the second base side connects the flow path of the fluid part to the first flow path and the second flow path formed in the base block using the conversion joint that can be connected to the fluid inlet of the first fluid part and the fluid outlet of the first fluid part.

### Effect of the Invention

According to the present invention, it is possible providing a conversion joint and an integrated fluid supply device having the conversion joint, which can use a fluid part having a size different from that of the fluid part corresponding to the base block is possible.

### BRIEF DESCRIPTION OF THE DRAWINGS

FIG. 1 is a perspective view illustrating an integrated fluid supply device for which a conversion joint according to an embodiment of the present invention is used.

FIG. 2 is a side view for explaining a case in which a first fluid part having a different size from that of a fluid part is to be installed so that the 1st base block and the 2nd base block may be bridged as shown in FIG. 1.

FIG. 3 is a perspective view of a conversion joint according to an embodiment of the present invention.

FIG. 4 is a side view of the conversion joint according to the embodiment of the present invention as viewed from the direction of the arrow C1 in FIG. 3.

FIG. 5 is a side view of the conversion joint according to the embodiment of the present invention as viewed from the direction of the arrow C2 in FIG. 3.

FIG. 6 is a plan view of the conversion joint according to the embodiment of the present invention as viewed from the direction of the arrow C3 in FIG. 3.

FIG. 7 is a side view showing a first fluid part connected to a first base block and a second base block using a conversion joint according to an embodiment of the present invention.

### MODE FOR CARRYING OUT THE INVENTION

Below, a mode for carrying out the present invention (hereinafter referred to as “embodiment”) will be described in detail with reference to the accompanying drawings.

In addition, the same elements are given the same numbers through the entire description of the embodiment.

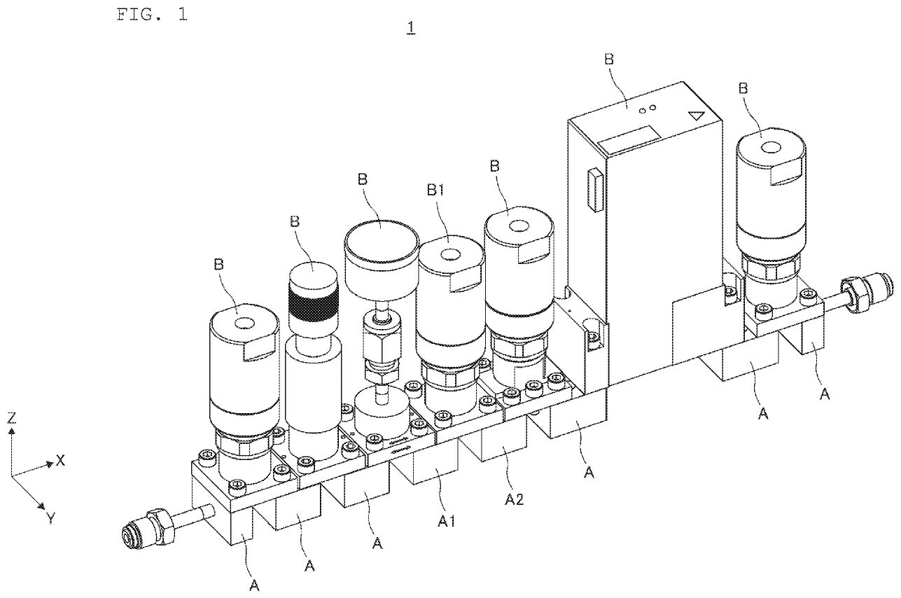

FIG. 1 shows a perspective view illustrating an integrated fluid supply device 1 to which a conversion joint 40 according to an embodiment of the present invention is to be used, and an integrated fluid supply device 1 using a base block A of about 1.5 inches.

Note that in the following description, in the XYZ axis shown in FIG. 1, the Z-axis direction is referred to as a first direction Z, the X-axis direction is referred to as a second direction X, and the Y-axis direction is referred to as a third direction Y, and the same applies to the other figures.

As shown in FIG. 1, the integrated fluid supply device 1 includes a plurality of base blocks A arranged in the second direction X which is the arrangement direction of the base blocks A, and fluid part B is installed so as to be a bridge between adjacent base blocks A, and each base block A is fixed at a predetermined position on a base plate (not shown).

Fluid part B is generally selected from manual valves, pressure transducers, regulators, filters, mass flow controllers, air operation valves, etc. and the order in which the parts are arranged is determined by the specification required for the gas supply line.

Therefore, depending on the specification, parts having other functions may be used in addition to the manual valve, the pressure transducer, the regulator, the filter, the mass flow controller, and the air operation valve for the fluid part B.

Note that FIG. 1 shows only a portion corresponding to one type of gas supply line, and in the integrated fluid supply device 1, similar gas supply lines are integrated so as to be aligned in the third direction Y in accordance with the number of necessary gas types.

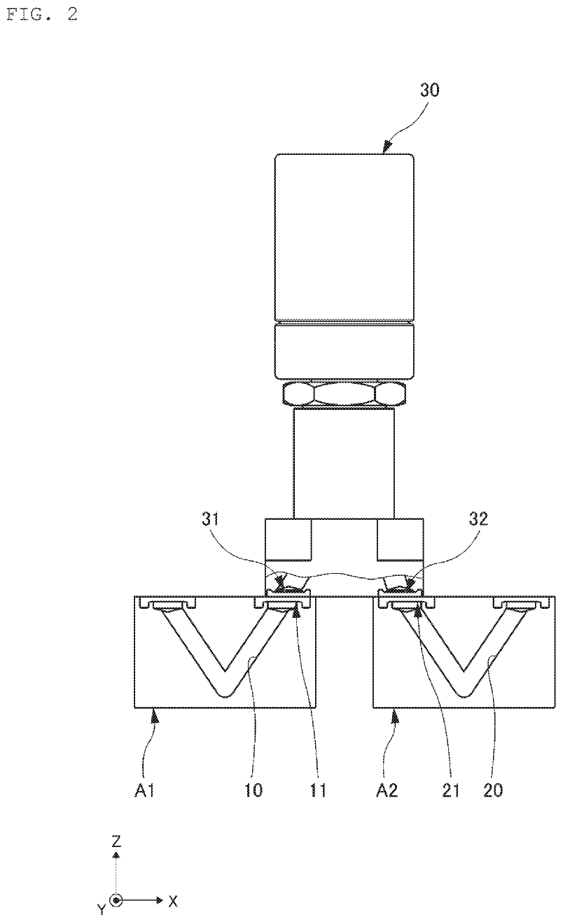

FIG. 2 is a side view illustrating a case when a first fluid part 30 (for example, an air operation valve for 1.125 inches) is replaced with a first fluid part 30 having a different size from the fluid part B1 (for example, an air operation valve for 1.5 inches) to be installed so as to be a bridge between the first base block A1 and the second base block A2 shown in FIG. 1.

Note that in FIG. 2, the first base block A1 and the second base block A2 are illustrated as cross-sectional views so that the first flow path 10 formed in the first base block A1 and the second flow path 20 formed in the second base block A2 can be seen.

In addition, for the first fluid part 30, a part of the periphery of the fluid inlet 31 and the fluid outlet 32 is depicted as a cross-sectional view so that the fluid inlet 31 and the fluid outlet 32 can be seen.

The 1.125 inch first fluid part 30 is generally smaller than the 1.5 inch fluid part B1, which is to be installed so as to be a bridge between the first base block A1 and the second base block A2, and as described above, the first base block A1 and the second base block A2 are fixed at predetermined positions on the base plate.

Therefore, as shown in FIG. 2, even if the first fluid part 30 is installed so as to be a bridge between the first base block A1 and the second base block A2, not only does the position of the one end side opening 11 of the first flow path 10 of the first base block A1 and the position of the fluid inlet 31 of the first fluid part 30 not match, but also since the size itself including the seal structure of the one end side opening 11 and the fluid inlet 31 does not match, it cannot be connected so that the fluid does not leak.

Similarly, not only the position of the other end side opening 21 of the second flow path 20 of the second base block A2 and the position of the fluid outlet 32 of the first fluid part 30 do not match, but also since the size itself including the seal structure of the other end side opening 21 and the fluid outlet 32 does not match, it cannot be connected so that the fluid does not to leak.

Therefore, by using the conversion joint 40 described below, the first base block A1 and the second base block A2 are able to be bridged even though the 1.125 inch first fluid part 30 is a different size from the 1.5 inch fluid part B1 to be installed, and can be installed so that the above-described fluid leakage does not occur.

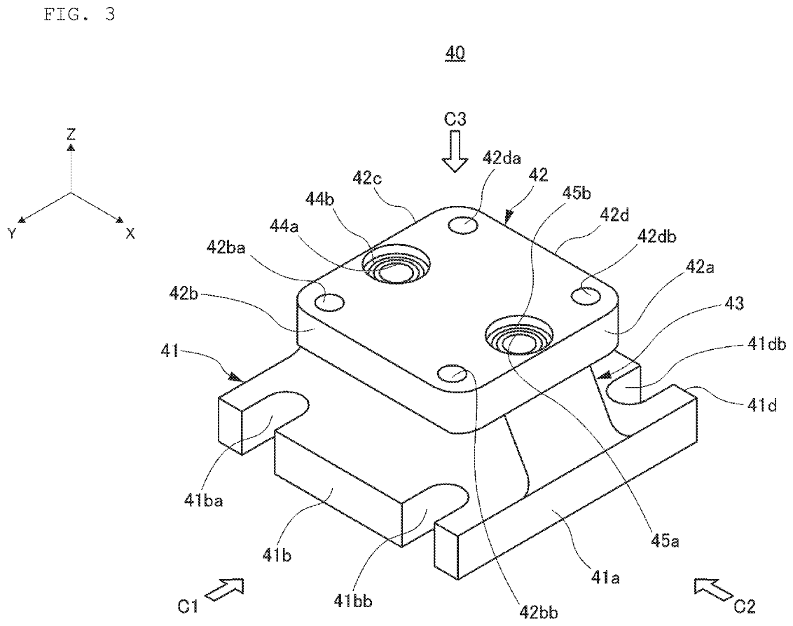

FIG. 3 is a perspective view of the conversion joint 40 of the present embodiment, and the lower side of FIG. 3 is the side where the first base block A1 and the second base block A2 are located, and the upper side is the side where the first fluid part 30 is located.

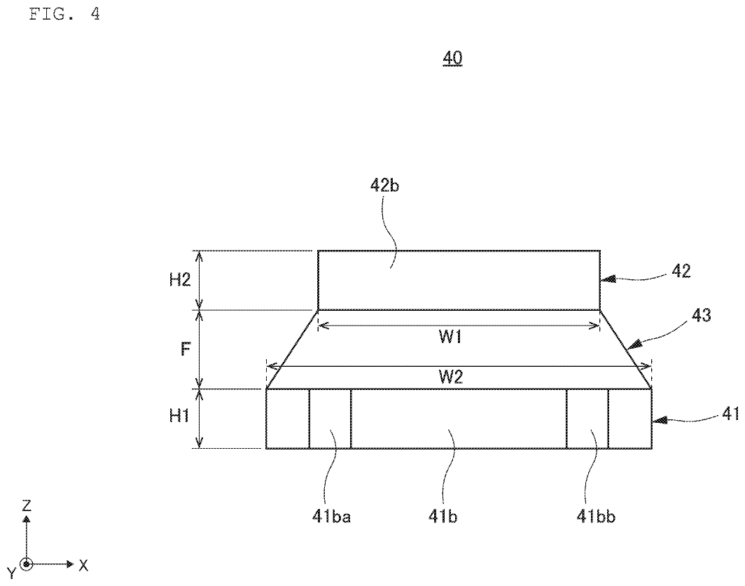

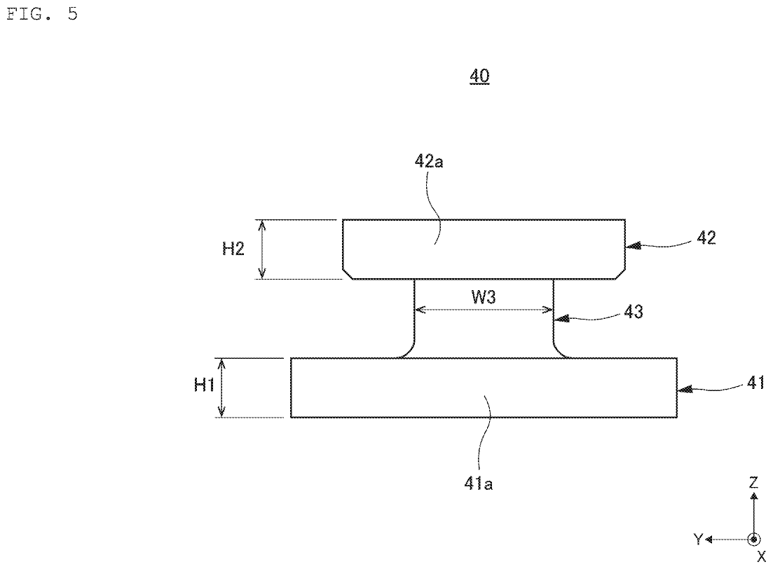

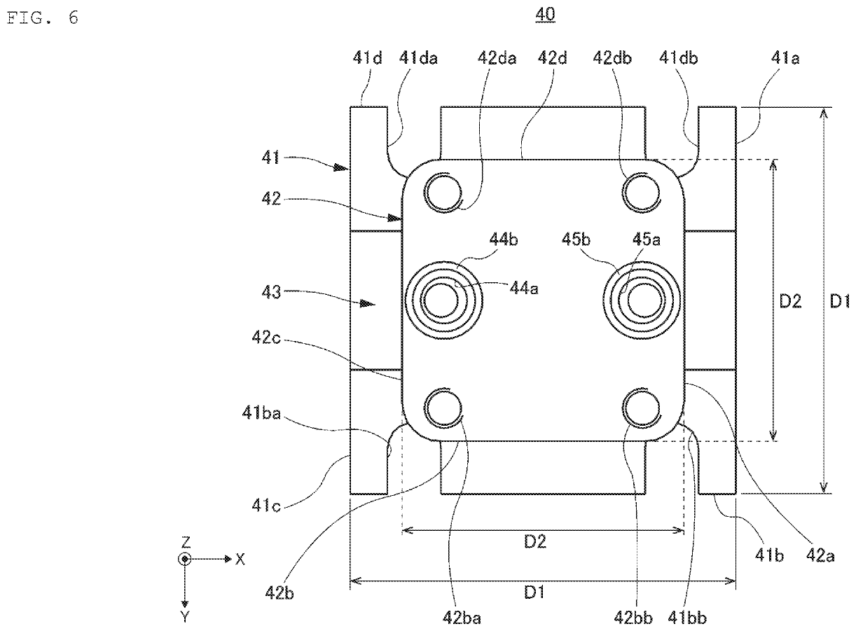

Also, FIG. 4 is a side view of the conversion joint 40 seen from the direction of the arrow C1 in FIG. 3; FIG. 5 is a side view of the conversion joint 40 seen from the direction of the arrow C2 in FIG. 3; and FIG. 6 is a plan view of the conversion joint 40 seen from the direction of the arrow C3 in FIG. 3.

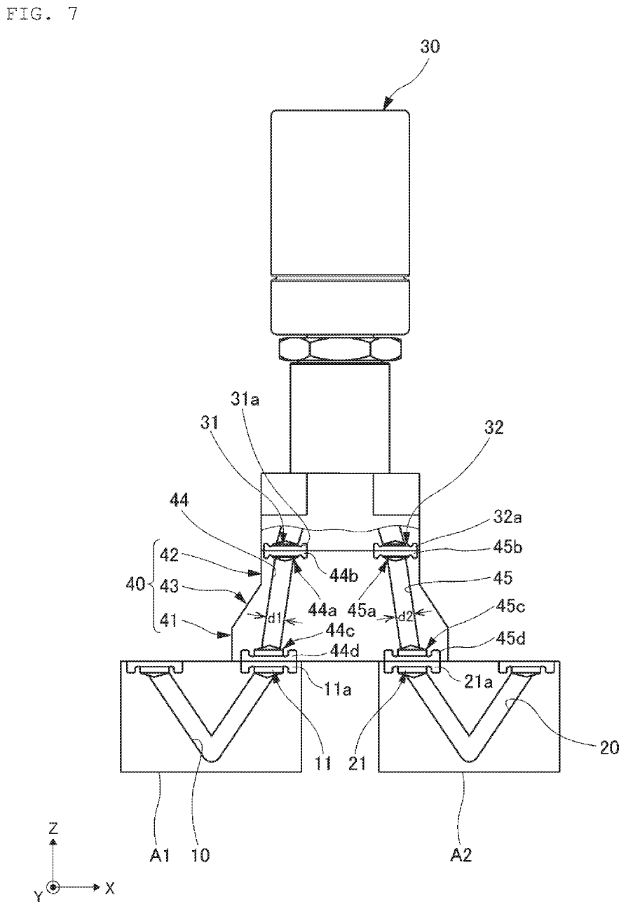

Further, FIG. 7 is a side view showing the connection of the first fluid part 30 to the first base block A1 and the second base block A2 using the conversion joint 40.

Note that, in FIG. 7, the first base block A1, the second base block A2, and the conversion joint 40 are depicted as cross-sectional views so that the flow paths of the first flow path 10 of the first base block A1, the second flow path 20 of the second base block A2, and the conversion joint 40 (the one end side flow path 44 connected to one end (the one end side opening 11) of the first flow path 10 of the first base block A1, and the other end side flow path 45 connected to the other end (the other end side opening 21) of the second flow path 20 of the second base block A2) can be seen.

Also, in FIG. 7, similarly to FIG. 2, a part around the fluid inlet 31 and the fluid outlet 32 is also drawn as a cross-sectional view of the first fluid part 30 so that the fluid inlet 31 and the fluid outlet 32 can be seen.

As shown in FIGS. 3 to 7, the conversion joint 40 includes a first base portion 41 disposed on the two base blocks A, base block A (first base block A1) having the first flow path 10 and base block A (second base block A2) having the second flow path 20 shown in FIGS. 1 and 2, a second base portion 42 separated from the first base portion 41 in a first direction Z away from the first base block A1 and the second base block A2, and an intermediate portion 43 positioned between the first base portion 41 and the second base portion 42 and connecting the first base portion 41 and the second base portion 42.

Note that, as will be described later, the second base portion 42 is a portion where the first fluid part 30 which has a different size from the fluid part B1 is mounted at the place where the conversion joint 40 of the two base blocks A (first base block A1 and second base block A2) are mounted.

Further, as shown in FIG. 7, the conversion joint 40 is provided with one end side flow path 44 penetrating through the second base portion 42, the intermediate portion 43, and the first base portion 41 and is connected to one end (one end side opening 11) of the first flow path 10 of the first base block A1 and the other end side flow path 45 that penetrates through the second base portion 42, the intermediate portion 43, and the first base section 41 and is connected to the other end (the other end side opening 21) of the second flow path 20 of the second base block A2.

Then, the first opening 44a on the second base portion 42 side of the one end side flow path 44 and the second opening 45a on the second base portion 42 side of the other end side flow path 45 are formed in such a manner that the separation distance between the first opening 44a and the second opening 45a is the same as the separation distance between the fluid inlet 31 of the first fluid part 30 and the fluid outlet 32 of the first fluid part 30, and the fluid inlet 31 of the first fluid part 30 and the fluid outlet 32 of the first fluid part 30 are set so as to be connectable.

Also, as shown in FIGS. 6 and 7, a first ring-shaped groove 44b for accommodating a seal member (for example, metal packing) is formed on the outer periphery of the first opening 44a, and this first ring-shaped groove 44b is also the same as the inlet-side ring-shaped groove 31a (see FIG. 7) that accommodates the seal member formed on the outer periphery of the fluid inlet 31 of the first fluid part 30.

For this reason, the sealing member used for the first fluid part 30 can be used as it is.

Similarly, as shown in FIGS. 6 and 7, a second ring-shaped groove 45b for accommodating a seal member is formed on the outer periphery of the second opening 45a, and this second ring-shaped groove 45b is also the same as the outlet side ring-shaped groove 32a (see FIG. 7) that accommodates a seal member formed on the outer periphery of the fluid outlet 32 of the first fluid part 30.

For this reason, the sealing member used for the first fluid part 30 can be used as it is.

On the other hand, the first inner diameter d1 of the one end side flow path 44 is set to an inner diameter substantially close to the opening diameter of the fluid inlet 31 of the first fluid part 30, and the first inner diameter d1 of the one end side flow path 44 between the first opening 44a and the third opening 44c on the first base portion 41 side of the one end side flow path 44 is a substantially uniform inner diameter.

Then, the third opening 44c has a diameter larger than the first inner diameter d1 of the one end side flow path 44 so as to have an inner diameter substantially the same as that of the one end side opening 11 of the first flow path 10 of the first base block A1, and the connection between the third opening 44c and the one end side opening 11 is made so as not to have a different diameter connection.

Further, as shown in FIG. 7, a third ring-shaped groove 44d for accommodating a seal member is formed on the outer periphery of the third opening 44c, and this third ring-shaped groove 44d is also the same as a ring-shaped groove on the one end side opening 11a for accommodating a seal member formed on the outer periphery of the one end side opening 11 of the first base block A1.

For this reason, the sealing member used for the first base block A1 can be used as it is.

Incidentally, although preventing the connection of different diameters by expanding the first inner diameter d1 of the one end side flow path 44 toward the third opening 44c side in a tapered manner is possible, in such a case, because the processing cost becomes high, the first inner diameter d1 of the one end side flow path 44 is preferably a substantially uniform inner diameter, and the third opening 44c is larger in diameter than the first inner diameter d1 of the one end side flow path 44 as in this embodiment.

Similarly, the second inner diameter d2 of the other end side flow path 45 is set to an inner diameter substantially close to the opening diameter of the fluid outlet 32 of the first fluid part 30, and the second inner diameter d2 of the other end side flow path 45 between the second opening 45a and the fourth opening 45c on the first base portion 41 side of the other end side flow path 45 is a substantially uniform inner diameter.

Then, the fourth opening 45c has a diameter larger than the second inner diameter d2 of the other end side flow path 45 so as to have an inner diameter substantially the same as that of the other end side opening 21 of the second flow path 20 of the second base block A2, so that the connection between the fourth opening 45c and the other end side opening 21 does not have a different-diameter connection.

Also, as shown in FIG. 7, a fourth ring-shaped groove 45d for accommodating a seal member is formed on the outer periphery of the fourth opening 45c, and this fourth ring-shaped groove 45d is also the same as a ring-shaped groove on the other end side opening 21a for accommodating a seal member formed on the outer periphery of the other end side opening 21 of the second base block A2.

For this reason, the sealing member used for 2nd base block A2 can be used as it is.

Also in this case, although the second inner diameter d2 of the other end side flow path 45 can be tapered so as to be tapered toward the fourth opening 45c, because doing so will increase processing costs, the second inner diameter d2 of the other end side flow path 45 is preferably set to be a substantially uniform inner diameter, and the fourth opening 45c is preferably larger than the second inner diameter d2 of the other end side flow path 45 like in this embodiment.

Note that similar to the manner described for the first opening 44a and the second opening 45a, the separation distance between the third opening 44c and the fourth opening 45c is formed so as to be the same as the separation distance between the one end side opening 11 of the first base block A1 and the other end side opening 21 of the second base block A2, and is set to be connectable to the one end side opening 11 and the other end side opening 21.

Incidentally, by using the conversion joint 40, the first base portion 41 is fixed to the first base block A1 and the second base block A2, and the first fluid part 30 is fixed to the second base portion 42; hereinafter, the structure and the like for fixing will be described.

As shown in FIG. 6, the first base portion 41 is formed in a substantially rectangular first outer shape, and in the present embodiment, the four side surfaces 41a, 41b, 41c, and 41d are each formed into a substantially regular first outer shape having a length D1.

Specifically, the width in the third direction Y of the first base block A1 and the second base block A2 shown in FIGS. 1 and 2 is about 39.0 [mm], and the length D1 is set to about 39.0 [mm].

Then, with respect to the first base portion 41, one opposite set of side surfaces (opposite side surfaces 41b and 41d) of the two opposite sets of side surfaces (opposite side surfaces 41b and 41d and opposite side surfaces 41a and 41c) is disposed along the second direction X that is the arrangement direction of the first base block A1 and the second base block A2 shown in FIG. 1.

The second direction X is also a direction from the fluid inlet to the fluid outlet of the fluid part B1 disposed on the first base block A1 and the second base block A2.

Therefore, in other words, the first base portion 41 is formed in a substantially rectangular first outer shape in which one opposite set of side surfaces (opposite side surfaces 41b and 41d) of the two opposite sets of side surfaces (opposite side surfaces 41b and 41d and opposite side surfaces 41a and 41c) is arranged along the second direction X in the direction from the fluid inlet to the fluid outlet of the fluid part B1 arranged on the first base block A1 and the second base block A2.

In this case, if the length D1 of the side surfaces 41a and 41c is longer than the width in the third direction Y of the first base block A1 and the second base block A2, then when the conversion joint 40 is arranged so as to be a bridge between the first base block A1 and the second base block A2, the first base portion 41 protrudes in the third direction Y side from the first base block A1 and the second base block A2.

However, as in the present embodiment, if the length D1 of the side surfaces 41a and 41c is adjusted to the width in the third direction Y of the first base block A1 and the second base block A2, such a bulge can be prevented from occurring, and interference with another gas supply line disposed adjacently can be avoided.

Also, in order to avoid interference with the adjacent 1.5 inch fluid part B (see FIG. 1), the length D1 of the side surfaces 41b and 41d is also adapted to the width in the third direction Y of the first base block A1 and the second base block A2.

Note that from this if the length D1 of the side surfaces 41a, 41c facing the second direction X that is the alignment direction of the first base block A1 and the second base block A2 and the side surfaces 41b, 41d facing the third direction Y orthogonal to the second direction X are both equal to or less than the width in the third direction Y of the first base block A1 and the second base block A2, for example with a 1.5 inch first base block A1 and second base block A2, then the length D1 is preferably about 39 [mm] or less.

Then, as shown in FIG. 6, for the first base portion 41, four screw penetration portions 41ba, 41bb, 41da, and 41db are provided at positions that form a rectangular shape on the side surfaces 41b, 41d facing each other.

Specifically, on the first base block A1 side of the side surfaces 41b, 41d facing each other of the first base portion 41, screw penetration portions 41ba and 41da are formed as notches opened in the side surfaces 41b and 41d of the first base portion at positions corresponding to the screw engagement portions formed in the first base block A1.

Also, on the second base block A2 side of the side surfaces 41b, 41d facing each other of the first base portion 41, screw through portions 41bb and 41db are formed as notches opened in the side surfaces 41b and 41d of the first base portion 41 at positions corresponding to screw engagement portions formed in the second base block A2.

Here, as can be seen from FIG. 6, the second base portion 42 has a second external shape different from the first external shape of the first base portion 41, and more specifically, an external shape smaller than the first external shape of the first base portion 41.

If done in this way, the four screw penetration portions 41ba, 41bb, 41da and 41db of the first base portion 41 are easily accessible.

On the other hand, the second base portion 42 has a second outer shape that is large enough to form screw engagement portions 42ba, 42bb, 42da, and 42db for fixing the first fluid part 30.

Therefore, although the second base portion 42 has a second outer shape smaller than the first outer shape of the first base portion 41, as shown in FIG. 6, when the second base portion 42 faces the front and the first base portion 41 and the second base portion 42 are viewed in the overlapping direction, because the second base portion 42 overlaps a part of the portion (R-shaped portion) where the screw of the screw penetration portions 41ba, 41bb, 41da and 41db is located, performing the operation of fixing the first base portion 41 to the first base block A1 and the second base block A2 with screws, from the upper side, is difficult.

Note that when the center of the part where the screw is located (R-shaped part) is used as a reference, the distance between the screw penetration portions 41ba and 41bb and between the screw penetration parts 41da and 41db is about 26.0 [mm], and the distance between the screw penetration parts 41ba and 41da and between the screw penetration parts 41bb and 41db is about 30.0 [mm].

Therefore, in the present embodiment, instead of the screw penetrating portions 41ba, 41bb, 41da, and 41db being formed as through holes, but are formed as notches, so that the screw can be inserted so as to slide from the side surfaces 41b and 41d of the first base portion 41 to the back side.

If this is done, because the fixing operation can be performed by sliding the screw from the side surfaces 41b and 41d of the first base portion 41 to the back side, turning the screw to the point where the screw can be lightly turned by the finger, increasing the distance between the upper surface of the screw and the second base portion 42, and then finally performing the re-tightening with a hexagonal wrench or the like, the workability can be improved.

Also, when the screw penetration portions 41ba, 41bb, 41da and 41db are formed as notches, because a screw having a long length can be used for the thickness H1 (see FIGS. 4 and 5) of the first base portion 41, the screw allowance can be increased, and can be firmly fixed.

Note that although in the present embodiment the thickness H1 of the first base portion 41 is 6.0 [mm], the thickness H1 of the first base portion 41 is preferably 4.0 [mm] or more so that sufficient strength is obtained, and is more preferably 5.0 [mm] or more, and still more preferably 6.0 [mm] or more.

On the other hand, when the thickness H1 becomes too thick, when taking into consideration the labor required for forming the screw penetration portions 41ba, 41bb, 41da, and 41db as the notches increases and the height in the first direction Z becomes high, the thickness H1 of the first base portion 41 is preferably 10.0 mm or less, more preferably 9.0 mm or less, and still more preferably 8.0 mm or less.

Next, looking at the second base portion 42, as shown in FIG. 6, similarly to the first base portion 41, the second base portion 42 is also formed in a substantially rectangular second outer shape, and in the present embodiment, the lengths of the four side surfaces 42a, 42b, 42c, and 42d are all formed in a substantially square second outer shape having a length D2, and specifically, the length D2 is set to about 28.5 [mm] so as to match the size of the bottom surface of the first fluid part 30.

Note that in the present embodiment, the example in which the second base portion 42 is chamfered with four corners as an R shape is shown, but the corners need not necessarily be chamfered.

Further, even when chamfering is performed, chamfering may be performed by cutting off straight corners instead of R-shaped chamfering.

This also applies to the first base portion 41.

That is, in the present embodiment, the first base portion 41 is not chamfered at four corners, but may be chamfered like the second base portion 42.

Then, for the second base portion 42, one opposite set of side surfaces (opposite side surfaces 21b and 42d) of the two opposite sets of side surfaces (opposite side surfaces 42b and 42d and opposite side surfaces 42a and 42c) is provided so as to be positioned along a second direction X that is the arrangement direction of the first base block A1 and the second base block A2 shown in FIG. 1.

Also, as shown in FIG. 6, four screw engagement portions 42ba, 42bb, 42da, and 42db provided at positions corresponding to screw through holes through which screws of the first fluid part 30 are passed are provided at positions forming a rectangular shape.

Specifically, when the center of the screw engaging portions 42ba, 42bb, 42da and 42db is taken as a reference, the distance between the screw engagement portions 42ba and 42bb and between the screw engaging portions 42da and 42db is about 20.0 [mm], and the distance between the screw engagement portions 42ba and 42da and between the screw engagement portions 42bb and 42db is about 21.8 [mm].

In addition, in the present embodiment, the thickness H2 (see FIGS. 4 and 5) of the second base portion 42 is set to 6.0 [mm] which is the same as the thickness H1 of the first base portion 41, but similarly to the first base portion 41, the thickness H2 of the second base portion 42 is preferably 4.0 [mm] or more, more preferably 5.0 [mm] or more, even more preferably 6.0 [mm] or more so that sufficient strength can be obtained, and if the thickness H2 is too thick, the height in the first direction Z is increased, so that the thickness H2 of the second base portion 42 is preferably 10.0 [mm] or less, more preferably 9.0 [mm] or less, and still more preferably 8.0 [mm] or less.

Next, when looking at the intermediate portion 43, as shown in FIG. 4, the second width of the intermediate portion 43 in the second direction X tapers from the width W1 of the second base portion 42 toward the width W2 of the first base portion 41.

Note that although in the present embodiment the intermediate portion 43 has a height F in the first direction Z of 8.0 [mm], if this height is low, because the one end side flow path 44 and the other end side flow path 45 to be described later are formed so as to be greatly inclined, forming a flow path becomes difficult.

On the other hand, if the height F is high, the height in the first direction Z is high.

Therefore, the height F is preferably 6.0 [mm] or more and 10.0 [mm] or less, and more preferably 7.0 [mm] or more and 9.0 [mm] or less.

Then, in this way, by expanding the second width in the second direction X from the second base portion 42 toward the first base portion 41, forming the one end side flow path 44 and the other end side flow path 45 so that the first opening 44a and the second opening 45a corresponding to the fluid inlet 31 and the fluid outlet 32 of the first fluid part 30 are able to be connected to the third opening 44c and the fourth opening 45c corresponding to the one end side opening 11 of the first base block A1 and the other end side opening 21 of the second base block A2.

On the other hand, as shown in FIG. 5, the first width W3 of the third direction Y orthogonal to the first direction Z and the second direction X of the intermediate portion 43 is larger than the first inner diameter d1 of the one end side flow path 44 (see FIG. 7) and the second inner diameter d2 of the second end side flow path 45 in order to form the one end side flow path 44 and the other end side flow path 45, and specifically, in the present embodiment, the first width W3 is about 14.0 [mm].

Then, the first width W3 is smaller than either of the distances (see length D1) between the opposite side surfaces 41b and 41d and the opposite side surfaces 41a and 41c) of the first outer shapes of the two first base portions 41 shown in FIG. 6, and is smaller than either of the distances (see length D2) between the opposite side surfaces 42b and 42d and the opposite side surfaces 42a and 42c) of the second outer shapes of the two second base portions 42, and the shape of the conversion joint 40 is constricted at the intermediate portion 43.

More specifically, the first width W3 is smaller than any distance between the four adjacent screw penetration portions 41ba, 41bb, 41da, and 41db of the first base portion 41, and is smaller than any distance between the four adjacent screw engagement portions 42ba, 42bb, 42da, and 42db of the second base portion 42.

By doing so, the four screw penetration portions 41ba, 41bb, 41da, and 41db of the first base portion 41 and the four screw engagement portions 42ba, 42bb, 42da, and 42db of the second base portion 42 can be formed.

However, when the four screw engagement portions 42ba, 42bb, 42da, and 42db of the second base portion 42 are formed so as to fit within the thickness H2 of the second base portion 42, paying attention to the four screw engagement portions 42ba, 42bb, 42da, and 42db of the second base portion 42 is not necessary, and the first width W3 may have a width sufficient to form the four screw penetration portions 41ba, 41bb, 41da, and 41db of the first base portion 41.

Although the present invention has been described based on the embodiments described above, the present invention is not limited to the embodiments, and needless to say various modifications can be made without departing from the gist of the present invention.

In the above embodiment, a case has been described in which the fluid part B1 is disposed so as to straddle two base blocks A of the base block A (first base block A1) having the first flow path 10 and the base block A (second base block A2) having the second flow path 20.

However, in some cases, both the first flow path 10 and the second flow path 20 are formed in one base block A, and the fluid part B1 is disposed on the one base block A.

Also in this case, when the first fluid part 30 having a size different from that of the fluid part B1 is disposed on the base block A, similar to that described in the above embodiment, there is a problem that the first fluid part 30 cannot be connected to the first flow path 10 and the second flow path 20, but such a problem can be solved by using the conversion joint 40.

Thus, the present invention is not limited to the embodiments described above, and various modifications are included in the technical scope of the present invention, which is obvious to a person skilled in the art from the description of the claims.

### DESCRIPTION OF REFERENCE SYMBOLS

1 Integrated Fluid Supply Device
10 First Flow Path
11 One End Side Opening
11a Ring-Shaped Groove On One End Side Opening
20 Second Flow Path
21 Other End Side Opening
21a Ring-Shaped Groove On Other End Side Opening
30 First Fluid Part
31 Fluid Inlet
31a Inlet Side Ring-Shaped Groove
32 Fluid Outlet
32a Outlet Side Ring-Shaped Groove
40 Conversion Joint
41 First Base Portion
41a, Side Surface
41b, 41c,
41d
41ba, Screw Penetration Portions
41bb, 41da,
41db
42 Second Base Portion
42a, Side Surface
42b, 42c,
42d
42ba, Screw Engagement Portions
42bb, 42da,
42db
43 Intermediate Portion
44 One End Side Flow Path
44a First Opening
44b First Ring-Shaped Groove
44c Third Opening
44d Third Ring-Shaped Groove
45 Other End Side Flow Path
45a Second Opening
45b Second Ring-Shaped Groove
45c Fourth Opening
45d Fourth Ring-Shaped Groove
A Base Block(s)
A1 First Base Block
A2 Second Base Block
B, B1 Fluid Parts
D1 Length
D2 Length
d1 First Inner Diameter
d2 Second Inner Diameter
F Height
H1, H2 Thickness
W1, W2 Width
W3 First Width
X Second Direction
Y Third Direction
Z First Direction

1. A conversion joint having flow paths connecting a first flow path in a first base block and a second flow path in a second base block, the conversion joint comprising:
a first base portion disposed on the first base block and the second base block,
a second base portion which is separated from the first base portion in a first direction away from the first base block and the second base block and on which a first fluid part is mounted having a size different from other fluid parts to be mounted on the first base and the second base block in the places where the conversion joint is mounted,
an intermediate portion located between the first base portion and the second base portion which connects the first base portion and the second base portion,
a one end side flow path penetrating the second base portion, the intermediate portion, and the first base portion and connected to one end of the first flow path of the first base block, and
another end side flow path penetrating the second base portion, the intermediate portion, and the first base portion and connected to one end of the second flow path of the second base block,
wherein a first opening of the second base portion of the one end side flow path and a second opening of the second base portion of the other end flow path are set to be connectable to a fluid inlet of the first fluid part and a fluid outlet of the first fluid part, respectively.

2. The conversion joint according to claim 1,
wherein the first base portion is formed to have a first outer shape having a substantially rectangular shape in which one of two sets of opposite side surfaces is disposed along a second direction with respect to a direction from the fluid inlet to the fluid outlet of the first fluid part,
wherein the second base portion is formed in a substantially rectangular shape having a second outer shape different from the first outer shape, and
wherein the intermediate portion has a first width in a third direction orthogonal to the first direction and the second direction which is larger than a first inner diameter of the one end side flow path and a second inner diameter of the other end side flow path, and the first width is smaller than either of the distances between opposite sides of the two first outer shapes.

3. The conversion joint of claim 2, wherein the intermediate portion has a first width that is less than either of the distances between the opposite side surfaces of the second outer shape having two sets.

4. The conversion joint according to claim 2,
wherein in the first base portion, four screw penetration portions are provided at positions forming a rectangular shape,
wherein in the second base portion, four screw engagement portions are provided at positions forming a rectangular shape, and
wherein the intermediate portion has a first width less than any distance between the four adjacent screw penetration portions and less than any distance between the four adjacent screw engagement portions.

5. The conversion joint according to claim 4,
wherein when viewed in a direction in which the first base portion and the second base portion overlap with each other with the second base portion facing a front, the second base portion overlaps at least part of a portion where a screw of the screw penetration portions is positioned, and
wherein the screw penetration portions are formed in the first base portion as notches opened to the side surface of the first base portion.

6. The conversion joint according to claim 2,
wherein the first inner diameter of the one end side flow path between the first opening and a third opening on the first base portion side of the one end side flow path is a substantially uniform inner diameter,
wherein the third opening has a diameter larger than the first inner diameter of the one end side flow path,
wherein the second inner diameter of the other end side flow path between the second opening and a fourth opening on the first base portion side of the other end side flow path is a substantially uniform inner diameter, and
wherein the fourth opening is larger in diameter than the second inner diameter of the other end side flow path.

7. An integrated fluid supply device comprising at least:
at least first and second base blocks;
a first fluid part;
a conversion joint comprising:
a first base portion disposed on the first base block and the second base block,
a second base portion which is separated from the first base portion in a first direction away from the first base block and the second base block and on which the first fluid part is mounted having a size different from other fluid parts to be mounted on the first base block and the second base block in the places where the conversion joint is mounted,
an intermediate portion located between the first base portion and the second base portion which connects the first base portion and the second base portion,
a one end side flow path penetrating the second base portion, the intermediate portion, and the first base portion and connected to one end of the first flow path of the first base block, and
another end side flow path penetrating the second base portion, the intermediate portion, and the first base portion and connected to one end of the second flow path of the second base block,
wherein a first opening of the second base portion of the one end side flow path and a second opening of the second base portion of the other end side flow path are set to be connectable to a fluid inlet of the first fluid part and a fluid outlet of the first fluid part, respectively.

8. (canceled)
